(19) United States
(12) Patent Application Publication
(10) Pub. No.: US 2024/0304371 A1
(43) Pub. Date: Sep. 12, 2024

(54) SEMICONDUCTOR ASSEMBLIES WITH RECESSED INDUCTORS, AND METHODS FOR MAKING THE SAME

(71) Applicant: Micron Technology, Inc., Boise, ID (US)

(72) Inventors: Dustin L. Holloway, Meridian, ID (US); Jonathan S. Parry, Boise, ID (US)

(21) Appl. No.: 18/431,817

(22) Filed: Feb. 2, 2024

Related U.S. Application Data
(60) Provisional application No. 63/451,406, filed on Mar. 10, 2023.

(51) Int. Cl. H01F 27/28; H01F 27/02; H01F 27/26; H01F 41/04; H01L 25/16

(52) U.S. Cl. CPC H01F 27/2804; H01F 27/022; H01F 27/266; H01F 27/2823; H01F 41/041; H01L 25/16; H01F 2027/2814

(57) ABSTRACT

A semiconductor assembly is provided. The assembly includes a substrate and an inductor. The inductor includes a magnetic core with a first row of first bond pads on a first side and a second row of second bonds pads on a second side, the second side being opposite to the first side. The inductor further includes a plurality of wire bonds, each wire bond connecting a topside of one of the first bond pads to a topside of one of the second bond pads by running over the magnetic core, and a plurality of electrical traces connecting an underside of one of the first bond pads to an underside of one of the second bond pads by running under the magnetic core and through the substrate.

### CROSS-REFERENCE TO RELATED APPLICATION(S)

The present application claims priority to U.S. Provisional Patent Application No. 63/451,406, filed Mar. 10, 2023, the disclosure of which is incorporated herein by reference in its entirety.

### TECHNICAL FIELD

The present disclosure generally relates to semiconductor device assemblies, and more particularly relates to semiconductor assemblies with recessed inductors, and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example semiconductor assembly.

FIG. 2 is a simplified schematic plan view of a semiconductor device assembly in accordance with embodiments of the present technology.

FIG. 3 is a simplified schematic plan view of a plurality of electrical traces in a substrate from a semiconductor assembly in accordance with embodiments of the present technology.

FIGS. 4-6 are simplified schematic cross-sectional views of semiconductor device assemblies in accordance with embodiments of the present technology.

FIG. 7 is a simplified schematic plan view of a semiconductor device assembly in accordance with embodiments of the present technology.

FIG. 8 is a schematic view showing a system that includes a semiconductor assembly configured in accordance with an embodiment of the present technology.

FIG. 9 is a flow chart illustrating a method of making a semiconductor assembly in accordance with an embodiment of the present technology.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is to include switching regulators. Switching regulators stabilize output voltage, and allow a semiconductor assembly to operate with less power dissipation. Switching regulators, however, have many disadvantages.

Of the several disadvantages that switching regulators present to semiconductor packaging, the primary obstacle is the need to include an inductor to store energy. Inductors are too large to include in semiconductor packages designed for special use cases, e.g., mobile devices.

To address these drawbacks and others, and to reap the benefits of switching regulators in smaller semiconductor package form factors, various embodiments of the present disclosure provide semiconductor assemblies with recessed inductors. In this disclosure, “partially recessed” is a variant covered by the term “recessed.” Although the disclosed technology could be used as part of a switching circuit, the applications of a semiconductor assembly with a recessed inductor extend into other domains as well (e.g., RF communication, a means of isolating high frequency noise to different supplies going to an ASIC, as part of packages built upon thin substrates, for the general purpose of noise rejection, power management, et cetera).

FIG. 1 shows a simplified schematic cross-sectional view of an example semiconductor assembly 100 with a recessed inductor 101. The recessed inductor 101 can produce an inductance measuring from a microhenry scale up to a millihenry scale. The semiconductor assembly 100 includes a substrate 102 which includes an upper surface. The substrate 102 can be a printed circuit board substrate, a silicon interposer, a silicon die, et cetera. The inductor 101 includes a magnetic core 103 having a first side and a second side, where the second side is opposite the first side. The magnetic core 103 can comprise a highly magnetically permeable material (e.g., ferrite, iron, nickel, cobalt, steel, molybdenum, aluminum, or any possible alloy or combination of the foregoing materials, with each other and with an epoxy, et cetera). The magnetic core 103 can be disposed directly on the upper surface of the substrate 102, as illustrated in FIG. 1. The magnetic core 103 can have a width between one tenth of a millimeter and one millimeter, a length between five-tenths of a millimeter and two millimeters, and a height between one tenth of a millimeter and one millimeter. Included in the inductor 101 is a first row of first bond pads disposed on the upper surface to the first side, wherein a first bond pad 140 from the first row of bond pads has a first topside 141 and a first underside 142. On the second side of the magnetic core, a second row of second bond pads is disposed. A second bond pad 150 from the second row of bond pads has a second topside 151 and a second underside 152. A plurality of electrical traces 106 can run in parallel through the substrate 102 and underneath the magnetic core 103. The plurality of electrical traces 106 can comprise an electrically conductive material (e.g., copper, aluminum, gold, et cetera) and can comprise a variety of different structures, including fuses, wiring, insulation, vias (e.g., blind vias, stacked vias, staggered vias, through-hole vias, buried vias, microvias, capped vias, plugged vias, not plated vias, et cetera), conductive pillars, and SIGNAL layers, among others. Each electrical trace 106 connects a first underside 142 of a first bond pad 104 to a second underside 152 of a second bond pad 150. Above the magnetic core 103, a plurality of wire bonds 107 run in parallel. The plurality of wire bonds can comprise an electrically conductive material (e.g., gold, aluminum, copper, et cetera). Each wire bond 107 connects a first topside 141 of a first bond pad 140 to a second topside 151 of a second bond pad 150. The wire bonds 107 can be bonded to the pads by thermocompression bonding, ultrasonic bonding, thermosonic bonding, or some combination of the foregoing methods. The assembly can also include a layer of adhesive or epoxy 108 between the magnetic core 103 and the substrate 102, as illustrated in FIG. 1. The layer of adhesive or epoxy 108 can comprise a polyester, a polyimide, an acrylic, and a modified or conductive epoxy, which can include a conductive material (e.g., silver, graphite, et cetera) and an epoxy resin.

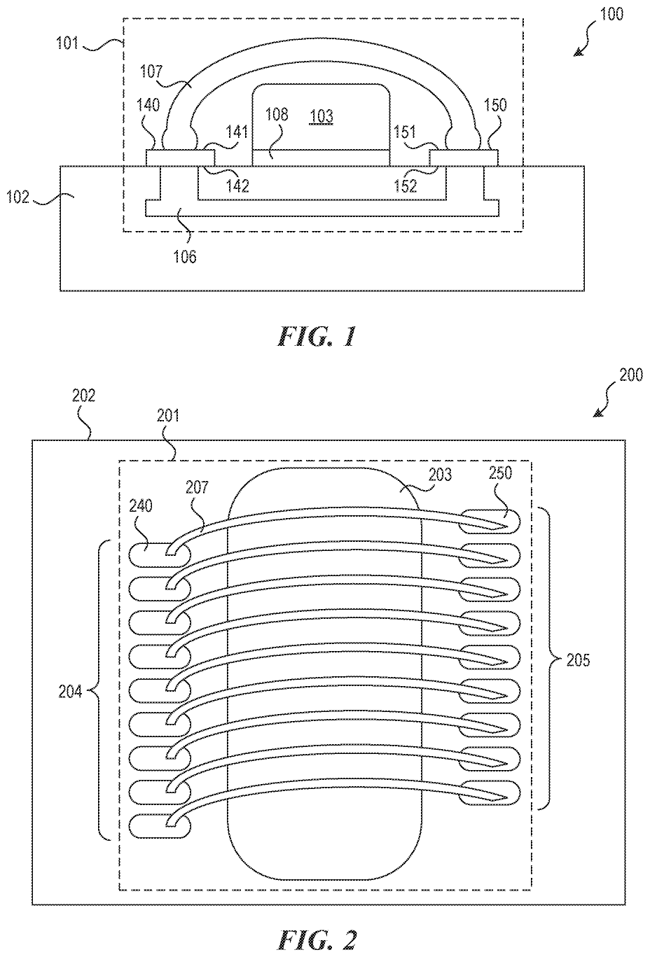

Viewing a potential semiconductor assembly 200 from a plan view in which the plurality of wire bonds 207 is visible, as in FIG. 2, alternative potential embodiments of the present technology can be seen. The assembly 200 can include a recessed inductor 201 which can further include a first row of first bond pads 204 and a second row of second bond pads 205. The first and second bond pads 204 and 205 can comprise thru-hole pads, surface-mount device pads, or some combination of the two. The pads 204 and 205 can comprise an electrically conductive material (e.g., copper), and they can have a shape (e.g., circular, square, rectangular, oval, teardrop, island-shaped, open-shaped, polygonal, or some combination of the foregoing shapes, et cetera). The second bond pads 205 can be offset to the first bond pads 204, as illustrated in FIG. 2. This offset can create a helical pattern in a plurality of wire bonds 207, as they can cross over a magnetic core 203 at an oblique angle to an axis along which the first bond pads extend, also illustrated in FIG. 2, so that each wire bond connects one of the first bond pads to a corresponding one of the second bond pads. The wire bonds 207 can be bonded to the pads by thermocompression bonding, ultrasonic bonding, thermosonic bonding, or some combination of the foregoing methods. This is just one of many potential embodiments, however, as the plurality of wire bonds 207 can also run straight over the magnetic core. The topmost and bottommost bond pads in the plurality can be left disconnected, or they can be connected to a separate pad or electrical conduit elsewhere on the assembly 200 (e.g., a switching regulator, a semiconductor device, et cetera).

Viewing this embodiment further, the recessed inductor 201 can produce an inductance measuring from a microhenry scale up to a millihenry scale. The semiconductor assembly 200 can include a substrate 202 which includes an upper surface. The substrate 202 can be a printed circuit board substrate, a silicon interposer, a silicon die, et cetera. The inductor 201 can include a magnetic core 203 having a first side and a second side, where the second side is opposite the first side. The magnetic core 203 can comprise a highly magnetically permeable material (e.g., ferrite, iron, nickel, cobalt, steel, molybdenum, aluminum, or any possible alloy or combination of the foregoing materials, with each other and with an epoxy, et cetera). The magnetic core 203 can be disposed on the upper surface of the substrate 202, as illustrated in FIG. 2. The magnetic core 203 can have a width between one tenth of a millimeter and one millimeter, a length between five-tenths of a millimeter and two millimeters, and a height between one tenth of a millimeter and one millimeter. A plurality of electrical traces can run in parallel through the substrate 202 and underneath the magnetic core 203, connecting the first row of first bond pads 204 to the second row of second bond pads 205. The assembly can also include a layer of adhesive or epoxy between the magnetic core 203 and the substrate 202.

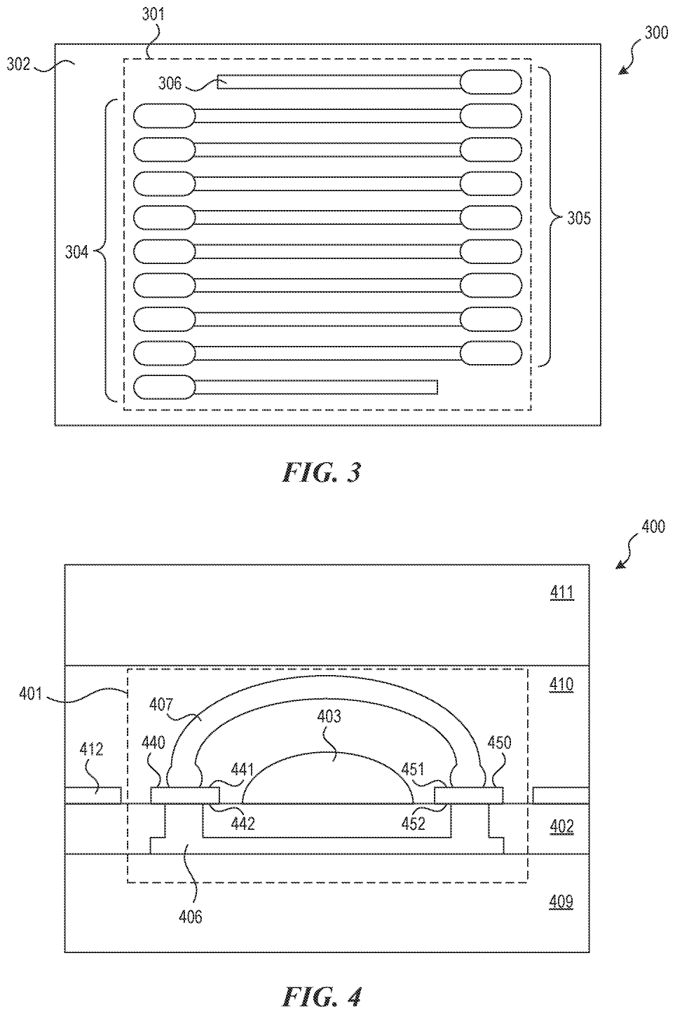

Examining a potential semiconductor assembly 300 with a recessed inductor 301 from a plan view in which a plurality of electrical traces 306 is visible running through a substrate 302, which can be seen in FIG. 3, it is possible to define other embodiments. In FIG. 3, the plurality of electrical traces 306 run directly across the assembly 300, so that each electrical trace connects one of a first row of first bond pads 304 to a corresponding one of a second row of second bond pads 305. The topmost and bottommost bond pads in the plurality can be left disconnected, as illustrated in FIG. 3, or they can be connected to a separate pad or electrical conduit elsewhere on the assembly 300 (e.g., a switching regulator, a semiconductor device, et cetera). This is just one of many potential embodiments, however, as the plurality of electrical traces 306 could also cross under a magnetic core at an oblique angle to an axis along which the first bond pads extend.

The recessed inductor 301 can include a magnetic core and a plurality of wire bonds on a topside of the substrate 302. Each wire bond can connect a first topside of a first bond pad from the first bond pads to a second topside of a second bond pad from the second bond pads. The substrate 302 can be a printed circuit board substrate, a silicon interposer, a silicon die, et cetera. The plurality of electrical traces 306 can comprise an electrically conductive material (e.g., copper, aluminum, gold, et cetera) and can comprise a variety of different structures, including fuses, wiring, insulation, vias (e.g., blind vias, stacked vias, staggered vias, through-hole vias, buried vias, microvias, capped vias, plugged vias, not plated vias, et cetera), conductive pillars, and SIGNAL layers, among others. Each electrical trace 306 can connect a first underside of a first bond to a corresponding second underside of a second bond pad.

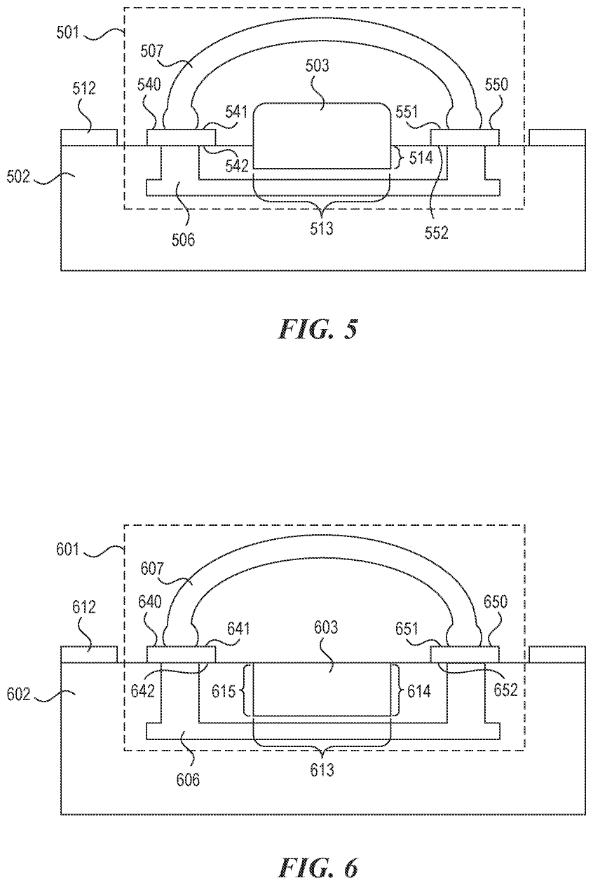

As another potential example, FIG. 4 illustrates a simplified schematic cross-sectional view of a semiconductor assembly 400 with a recessed inductor 401, in which a plurality of electrical traces 406 run through a substrate 402 under a magnetic core 403, and connect a first bond pad 440 to a second bond pad 450 by a first underside 442 and a second underside 452. The substrate 402 can comprise a metal layer or an interlayer dielectric, as illustrated in FIG. 4, and can be disposed over a first interposer or a first die 409. A layer of adhesive encapsulant 410 can encapsulate the inductor 401 and cover the upper surface of the substrate 402. The layer of adhesive encapsulant 410 can comprise materials from a Die Attach Film process or a Film Over Wire process. A second interposer or a second die 411 can be disposed on top of the layer of adhesive encapsulant 410. Additionally, the upper surface of the substrate 402 can be partially covered by a passivation layer 412 (e.g., a polyimide), which can be used as a high-temperature adhesive, a photoresist, or a mechanical stress buffer.

The first bond pad 440 can be one of many bond pads forming a first row of bond pads, and the second bond pad 450 can be one of many bond pads forming a second row of bond pads, neither row of bond pads being visible in the FIG. 4 cross-sectional view. Above the magnetic core 403 a plurality of wire bonds 407 can run in parallel. Each wire bond 407 can connect a first topside 441 of the first bond pad 440 to a second topside 451 of the second bond pad 450. The assembly can also include a layer of adhesive or epoxy between the magnetic core 403 and the substrate 402.

In contrast to the previous figures, FIG. 5 portrays a simplified schematic cross-sectional view of a semiconductor device assembly 500 with a recessed inductor 501. The assembly 500 can have a substrate 502 with an upper surface which can have a cavity 513 with a depth 514. The inductor 501 can have a magnetic core 503 disposed in the cavity 513 up to the depth 514. The inductor 501 can further include a first bond pad 540 from a first row of bond pads, the first bond pad 540 having a first topside 541 and a first underside 542. On a second side of the magnetic core, a second bond pad 550 from a second row of bond pads can be disposed, the second bond pad having a second topside 551 and a second underside 552. A plurality of electrical traces 506 can run in parallel through the substrate 502 and underneath the magnetic core 503. Each electrical trace 506 can connect the first underside 542 of the first bond pad 540 to the second underside 552 of the second bond pad 550. Above the magnetic core 503, a plurality of wire bonds 507 can run in parallel. Each wire bond 507 can connect the first topside 541 of the first bond pad 540 to the second topside 551 of the second bond pad 550. The assembly can also include a layer of adhesive or epoxy between the magnetic core 503 and the substrate 502.

Continuing on this theme, FIG. 6 illustrates a simplified schematic cross-sectional view of a semiconductor device assembly 600 in which a depth 614 of a cavity 613 is equal to a height 615 of a magnetic core 603 belonging to a recessed inductor 601, the magnetic core being disposed in the cavity 613. The inductor 601 can further include a first bond pad 640 from a first row of bond pads, the first bond pad 640 having a first topside 641 and a first underside 642. On a second side of the magnetic core, a second bond pad 650 from a second row of bond pads can be disposed, the second bond pad having a second topside 651 and a second underside 652. A plurality of electrical traces 606 can run in parallel through the substrate 602 and underneath the magnetic core 603. Each electrical trace 606 can connect the first underside 642 of the first bond pad 640 to the second underside 652 of the second bond pad 650. Above the magnetic core 603, a plurality of wire bonds 607 can run in parallel. Each wire bond 607 can connect the first topside 641 of the first bond pad 640 to the second topside 651 of the second bond pad 650. The assembly can also include a layer of adhesive or epoxy between the magnetic core 603 and the substrate 602.

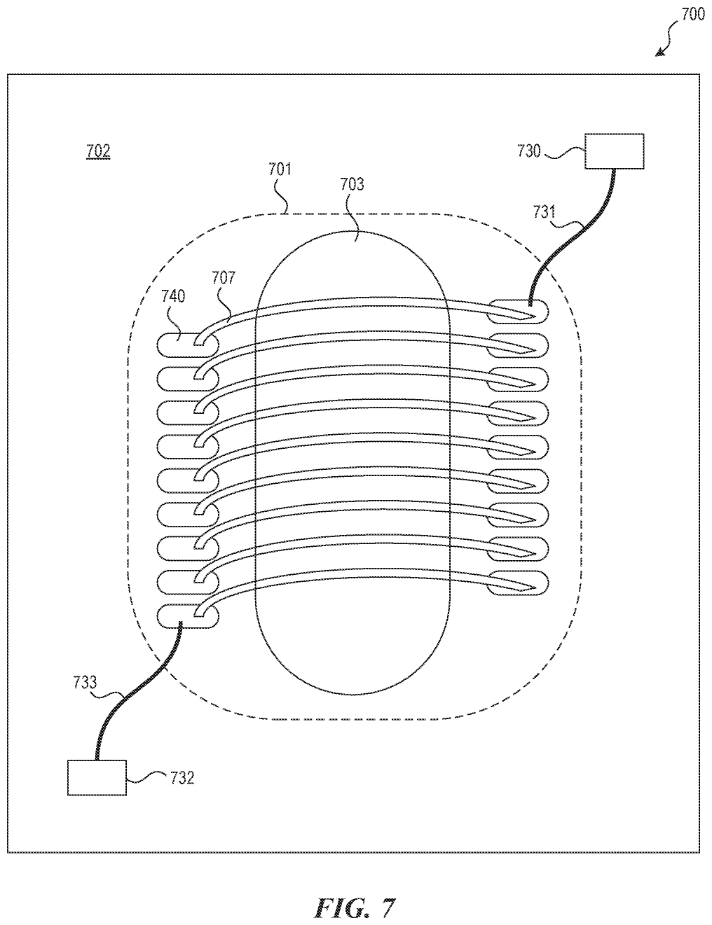

In the foregoing example embodiments, we explored semiconductor assemblies that included a recessed inductor. In FIG. 7 a different embodiment of the present technology is illustrated in simplified schematic plan view, the example embodiment being a semiconductor device assembly 700 with a recessed inductor 701. The inductor 701 can include a second row of second bond pads 705 which can be offset to a first row of first bond pads 704, as illustrated in FIG. 7. This offset can create a helical pattern in a plurality of wire bonds 707 in which each wire bond connects one first bond pad to a corresponding one second bond pad, from the first bond pads 704 and second bond pads 705 respectively, by crossing over a magnetic core 703, also illustrated in FIG. 7. Alternatively, the plurality of wire bonds 707 can run straight over the magnetic core 703, parallel to a side of the device assembly. In either embodiment, the topmost and bottommost bond pads in the plurality can be left disconnected, or they can be connected to a separate pad or electrical conduit somewhere else on the device assembly 700. Illustrating this example embodiment, in Figure the device assembly 700 includes a first electrical connection 731 to a semiconductor device 730 as well as a second electrical connection 733 to a switching regulator 732. Additionally, a plurality of electrical traces can run through the substrate 702 under the magnetic core 703. The traces can run directly across the device assembly 700, parallel to a side of the device assembly 700, and connect an underside of the first row of bond pads 704 to an underside of the second row of bond pads 705. The plurality of electrical traces can also cross under the magnetic core 703 at an oblique angle to an axis along which the first bond pads extend.

The semiconductor device assembly 700 can further include a substrate 702 with an upper surface, on which the magnetic core 703 can be disposed. Alternatively, the substrate 702 can have a cavity 713 with a depth 714 in the upper surface, and the magnetic core 703 can be disposed in the cavity up to the depth. Going further with this idea, the depth of the cavity in which the magnetic core 703 is disposed can be equal to a height of the magnetic core 703. The substrate 702 can be a printed circuit board substrate, a silicon interposer, a silicon die, or a metal layer, et cetera. Furthermore, the substrate can be disposed over a first interposer or a first die, with a layer of adhesive encapsulant material encapsulating the inductor 701 and covering the upper surface of the substrate 702. A second interposer or a second die can also be disposed on top of the layer of adhesive encapsulant material. Additionally, the upper surface of the substrate 702 can be partially covered by a passivation layer (e.g., a polyimide), which can be used as a high-temperature adhesive, a photoresist, or a mechanical stress buffer.

Although in the foregoing example embodiments the semiconductor device assemblies have been illustrated and described as including a single semiconductor device, in other embodiments assemblies can be provided with additional semiconductor devices. For example, the single semiconductor device illustrated in FIG. 7 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 1-7 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

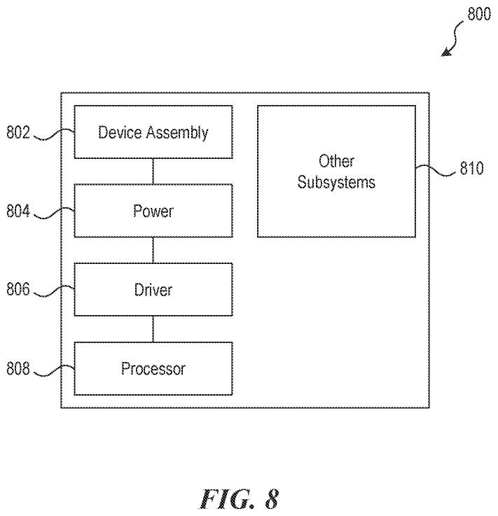

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly (e.g., or a discrete semiconductor device) 802, a power source 804, a driver 806, a processor 808, and/or other subsystems or components 810. The semiconductor device assembly 802 can include features generally similar to those of the semiconductor devices described above with reference to FIGS. 1-7. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances and other products. Components of the system 800 may be housed in a single unit or distributed over multiple, interconnected units (e.g., through a communications network). The components of the system 800 can also include remote devices and any of a wide variety of computer readable media.

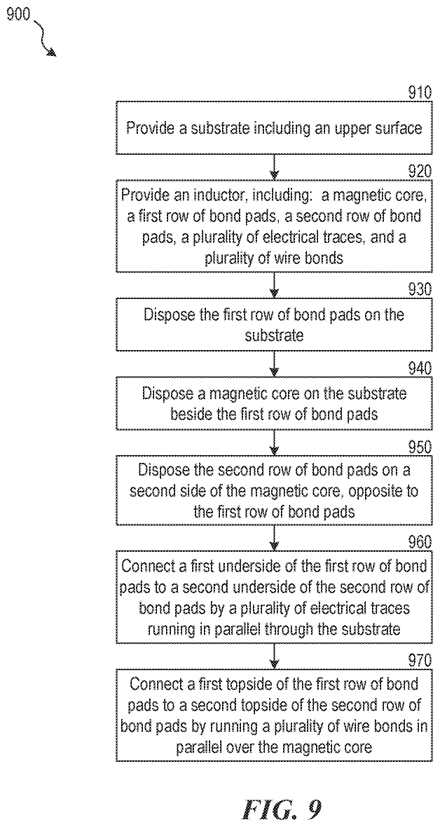

FIG. 9 is a flow chart illustrating a method 900 of making a semiconductor assembly. The method includes providing a substrate including an upper surface (box 910). The method further includes providing an inductor, including: a magnetic core, a first row of first bond pads, a second row of second bond pads, a plurality of electrical traces, and a plurality of wire bonds (box 920). The method further includes disposing the first row of first bond pads on the substrate (box 930). The method further includes disposing a magnetic core on the substrate beside the first row of first bond pads (box 940). The method further includes disposing the second row of second bond pads on a second side of the magnetic core, opposite to the first row of first bond pads (box 950). The method further includes connecting a first underside of a first bond pad from the first bond pads to a second underside of a corresponding second bond pad from the second bond pads by an electrical trace from the plurality of electrical traces, such that the plurality of electrical traces run in parallel through the substrate (box 960). The method further includes connecting a first topside of the first bond pad to a second topside of the corresponding second bond pad by a wire bond from the plurality of wire bonds, such that the plurality of wire bonds run in parallel over the magnetic core (box 970).

The method 900 can further include disposing a semiconductor device and a switching circuit on the substrate. After this additional step, the method 900 can finally include electrically connecting the inductor to the semiconductor device, as well as electrically connecting the inductor to the switching circuit to form a switching regulator.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor assembly, comprising:
a substrate, including an upper surface; and
an inductor, including:
a magnetic core having a first side and a second side, wherein the second side is opposite to the first side,
a first row of first bond pads disposed on the upper surface on the first side, wherein each first bond pad has a first topside and a first underside,
a second row of second bond pads disposed on the upper surface on the second side, wherein each second bond pad has a second topside and a second underside,
a plurality of electrical traces running in parallel through the substrate and underneath the magnetic core, each electrical trace connecting the first underside of one of the first bond pads to the second underside of a corresponding one of the second bond pads, and
a plurality of wire bonds running in parallel over the magnetic core, each wire bond connecting the first topside of one of the first bond pads to the second topside of a corresponding one of the second bond pads.

2. The semiconductor assembly of claim 1, further comprising a layer of adhesive or epoxy between the magnetic core and the substrate.

3. The semiconductor assembly of claim 1, wherein the magnetic core is disposed directly on the upper surface.

4. The semiconductor assembly of claim 1, wherein the upper surface has a cavity with a depth, and wherein the magnetic core is disposed in the cavity.

5. The semiconductor assembly of claim 4, wherein the depth is equal to a height of the magnetic core.

6. The semiconductor assembly of claim 1, wherein the second row of bond pads is offset to the first row of bond pads.

7. The semiconductor assembly of claim 6, wherein the plurality of wire bonds crosses over the magnetic core at an oblique angle to an axis along which the first bond pads extend.

8. The semiconductor assembly of claim 6, wherein the plurality of electrical traces crosses under the magnetic core at an oblique angle to an axis along which the first bond pads extend.

9. The semiconductor assembly of claim 1, wherein the substrate comprises an interlayer dielectric having the upper surface, the interlayer dielectric disposed over a first interposer or a first die, and wherein the assembly further comprises:
a layer of encapsulant material encapsulating the inductor and covering the upper surface of the interlayer dielectric; and
a second interposer or a second die disposed on top of the layer of encapsulant material.

10. A semiconductor device assembly, comprising:
a substrate, including an upper surface;
a semiconductor device disposed on the substrate; and
a switching regulator disposed on the substrate, the switching regulator including a switching circuit and an inductor, the inductor having:
a magnetic core having a first side and a second side, wherein the second side is opposite to the first side,
a first row of first bond pads disposed on the upper surface on the first side, wherein each first bond pad has a first topside and a first underside,
a second row of second bond pads disposed on the upper surface on the second side, wherein each second bond pad has a second topside and a second underside,
a plurality of electrical traces running in parallel through the substrate and underneath the magnetic core, each electrical trace connecting the first underside of one of the first bond pads to the second underside of a corresponding one of the second bond pads,
a plurality of wire bonds running in parallel over the magnetic core, each wire bond connecting the first topside of one of the first bond pads to the second topside of a corresponding one of the second bond pads,
a first electrical connection to the switching circuit, and
a second electrical connection to the semiconductor device.

11. The semiconductor device assembly of claim 10, further comprising a layer of adhesive or epoxy between the magnetic core and the substrate.

12. The semiconductor device assembly of claim 10, wherein the magnetic core is disposed directly on the upper surface.

13. The semiconductor device assembly of claim 10, wherein the upper surface has a cavity with a depth, and wherein the magnetic core is disposed in the cavity.

14. The semiconductor device assembly of claim 13, wherein the depth is equal to a height of the magnetic core.

15. The semiconductor device assembly of claim 10, wherein the second row of bond pads is offset to the first row of bond pads.

16. The semiconductor device assembly of claim 15, wherein the plurality of wire bonds crosses over the magnetic core at an oblique angle to an axis along which the first bond pads extend.

17. The semiconductor device assembly of claim 15, wherein the plurality of electrical traces crosses under the magnetic core at an oblique angle to an axis along which the first bond pads extend.

18. The semiconductor device assembly of claim 10, wherein the substrate comprises an interlayer dielectric having the upper surface, the interlayer dielectric disposed over a first interposer or a first die, and wherein the device assembly further comprises:
a layer of encapsulant material encapsulating the inductor and covering the upper surface of the interlayer dielectric; and
a second interposer or a second die disposed on top of the layer of encapsulant material.

19. A method of making a semiconductor assembly, the method comprising:
providing a substrate, including an upper surface;
forming an inductor by:
disposing a magnetic core on the upper surface, the magnetic core including a first side and a second side opposite to the first side,
forming a first row of first bond pads on the first side of the magnetic core, each first bond pad having a first topside and a first underside, and
forming a second row of second bond pads on the second side of the magnetic core, each second bond pad having a second topside and a second underside;
connecting each first underside of one of the first bond pads to a second underside of a corresponding one of the second bond pads by running an electrical trace through the substrate, wherein a plurality of electrical traces comprises the electrical trace, and wherein the plurality of electrical traces run in parallel; and
connecting each first topside of one of the first bond pads to a second topside of a corresponding one of the second bond pads by running a wire bond over the magnetic core, wherein a plurality of wire bonds comprise the wire bond, and wherein the plurality of wire bonds run in parallel.

20. The method of claim 19, further comprising:
disposing a semiconductor device on the substrate;
disposing a switching circuit on the substrate;
electrically connecting the inductor to the semiconductor device; and
electrically connecting the inductor to the switching circuit to form a switching regulator.
